(19) United States
(12) Patent Application Publication
(10) Pub. No.: US 2017/0170381 A1
(43) Pub. Date: Jun. 15, 2017

(54) STRUCTURES AND FABRICATION METHODS OF FLEXIBLE THERMOELECTRIC DEVICES

(71) Applicant: The Regents of the University of California, Oakland, CA (US)

(72) Inventors: Kate J. Norris, Los Altos, CA (US); Nobuhiko Kobayashi, Sunnyvale, CA (US)

(21) Appl. No.: 15/282,997

(22) Filed: Sep. 30, 2016

Related U.S. Application Data
(63) Continuation-in-part of application No. 14/668,679, filed on Mar. 25, 2015, now abandoned.
(60) Provisional application No. 61/979,094, filed on Apr. 14, 2014.
(60) Provisional application No. 61/982,774, filed on Apr. 22, 2014.
(60) Provisional application No. 61/983,290, filed on Apr. 23, 2014.
(60) Provisional application No. 61/982,781, filed on Apr. 22, 2014.
(60) Provisional application No. 61/982,654, filed on Apr. 22, 2014.
(60) Provisional application No. 61/993,826, filed on May 15, 2014.

(51) Int. Cl. H01L 35/32; H01L 35/34; H01L 35/14; H01L 35/30; H01L 35/22; H01L 35/26

(52) U.S. Cl. CPC H01L 35/32; H01L 35/22; H01L 35/26; H01L 35/14; H01L 35/30; H01L 35/34

(57) ABSTRACT

A thermoelectric device is provided that includes a first flexible copper substrate having a carbon layer disposed on a polycrystalline flexible copper foil, a first nanowire structure disposed on the carbon layer, where the first nanowire structure includes a first lateral film layer disposed on the distal ends of the first nanowire structure, where the first lateral film layer connects the first nanowire structure distal ends, a second nanowire structure disposed on the first lateral film layer, where the second nanowire structure includes a second lateral film layer disposed on distal ends of the second nanowire structure, where the second lateral film layer connects the second nanowire structure distal ends, and a second flexible copper substrate disposed on the second lateral film layer.

### CROSS-REFERENCE TO RELATED APPLICATIONS

This application is a continuation-in-part of U.S. patent application Ser. No. 14/668,679 filed Mar. 25, 2015, which is incorporated herein by reference. U.S. patent application Ser. No. 14/668,679 claims priority to U.S. Provisional Patent Application 61/979,094 filed Apr. 14, 2014, which is incorporated herein by reference. U.S. patent application Ser. No. 14/668,679 claims priority to U.S. Provisional Patent Application 61/982,774 filed Apr. 22, 2014, which is incorporated herein by reference. U.S. patent application Ser. No. 14/668,679 claims priority to U.S. Provisional Patent Application 61/983,290 filed Apr. 23, 2014, which is incorporated herein by reference. U.S. patent application Ser. No. 14/668,679 claims priority to U.S. Provisional Patent Application 61/982,781 filed Apr. 22, 2014, which is incorporated herein by reference. U.S. patent application Ser. No. 14/668,679 claims priority to U.S. Provisional Patent Application 61/982,654 filed Apr. 22, 2014, which is incorporated herein by reference. U.S. patent application Ser. No. 14/668,679 claims priority to U.S. Provisional Patent Application 61/993,826 filed May 15, 2014, which is incorporated herein by reference.

### STATEMENT OF GOVERNMENT SPONSORED SUPPORT

This invention was made with Government support under contract DGE-0809125 awarded by National Science Foundation (NSF), and under contract SBIR-NNX11CE14P awarded by National Aeronautics and Space Administration (NASA). The Government has certain rights in this invention.

### FIELD OF THE INVENTION

The present invention relates generally to nanowire structures. More particularly, the invention relates to the growth of silicon core-shell nanowires with a crystalline-core and a polycrystalline-shell on grapheme layered flexible copper substrates.

### BACKGROUND OF THE INVENTION

Copper is a low cost material with its properties as electrically and thermally conducting making it an ideal electrode for thermoelectric devices. However, growth of semiconductors directly on metallic substrates is a challenge. As a result, semiconductor nanowires are commonly grown on single-crystal semiconductor substrates with a few exceptions. The growth of III-V compound semiconductor nanowires using copper seed was recently demonstrated, however, the demonstration was on a single crystalline substrate. Growing Si on copper directly results in a polycrystalline film, which is partly related to the lattice mismatch between the two materials. What is needed is a method to grow semiconductor nanowires on copper by the use of a carbon layer.

### SUMMARY OF THE INVENTION

To address the needs in the art, a thermoelectric device is provided that includes a first flexible copper substrate having a carbon layer disposed on a polycrystalline flexible copper foil, a first nanowire structure disposed on the carbon layer, where the first nanowire structure includes a first lateral film layer disposed on the distal ends of the first nanowire structure, where the first lateral film layer connects the first nanowire structure distal ends, a second nanowire structure disposed on the first lateral film layer, where the second nanowire structure includes a second lateral film layer disposed on distal ends of the second nanowire structure, where the second lateral film layer connects the second nanowire structure distal ends, and a second flexible copper substrate disposed on the second lateral film layer.

According to one aspect of the invention, the polycrystalline copper foil includes a grapheme layer disposed on a flexible copper foil.

In another aspect of the invention, the first nanowire structure includes silicon nanowires. Here, the silicon nanowires include a core-shell structure, where the core structure includes a crystalline-core structure through which electrical conduction is maintained, where the shell structure includes a polycrystalline-shell structure through which heat conduction is reduced.

In a further aspect of the invention, the first lateral film layer includes a silicon layer.

According to one aspect of the invention, the second nanowire structure includes indium phosphide nanowires.

In one aspect of the invention, the second lateral film layer includes a silicon layer.

According to another embodiment of the invention a thermoelectric device is provided that includes a flexible copper substrate having a graphene layer disposed on a polycrystalline copper foil a nanowire structure disposed on the graphene layer, where the nanowire structure includes a lateral film layer disposed on the ends of the nanowire structure, where the lateral film layer connects the nanowire structure ends, and a second flexible copper substrate disposed on the lateral film layer.

According to one aspect of the invention first nanowire structure includes silicon nanowires. Here, the silicon nanowires include a core structure and a shell structure, where the core structure includes a crystalline-core structure through which electrical conduction is maintained, where the shell structure includes a polycrystalline-shell structure through which heat conduction is reduced.

In another aspect of the invention, the first lateral film layer includes a silicon layer.

In a further embodiment, the first nanowire structure includes Group III-V, Group IV, or Group V-VI nanowires.

### BRIEF DESCRIPTION OF THE DRAWINGS

FIGS. 1A-1C show schematic views of embodiments of the current invention.

FIG. 2 shows Raman spectroscopic data taken from the copper substrate treated with carbon showing the distinct graphene peaks, G and 2D, with the background PL signal removed, according to one embodiment of the current invention.

FIGS. 3A-3D show scanning electron microscope (SEM) images of the Silicon nanowires grown on copper at different magnifications showing in (3A) a high density of nanowires over a large area, (3B) slightly more zoomed in image showing that the nanowires are longer than 10 μm, (3C) that the nanowires are intersecting creating a network, (3D) a single nanowire with a diameter of ˜120 nm, according to the current invention.

FIGS. 4A-4D show bright field Transmission Electron microscopy image of (4A) an Silicon nanowire showing signs of two regions and a rough surface with a diameter of ˜100 nm, (4B) the crystalline core of the nanowire 11 nm in diameter, (4C) selective area diffraction of the nanowire showing polycrystalline rings and single crystalline bright spots indicating that the core is in fact single crystalline while the outer shell is polycrystalline and, (4D) the outer shell of the nanowire showing polycrystalline features, according to the current invention.

FIG. 5 shows X-ray diffraction of the Silicon nanowire network grown on copper foil confirming the presence of copper and silicon, according to the current invention.

FIGS. 6A-6C show finite element analysis of three segments of silicon showing a large thermal gradient across a polycrystalline segment indicating low thermal conductivity, and small thermal gradient across a single crystalline segment indicating high thermal conductivity, and another large thermal gradient across a Silicon segment with the core-shell structure seen in our TEM imaging of the sample of interest indicating a low thermal conductivity, according to the current invention.

FIGS. 7A-7D show SEM images of indium phosphide grown by MOCVD, (7A) in the form of a polycrystalline layer grown on copper not treated with carbon. The scale bar is 1000 nm, and (7B) in the form of poly-crystalline nanowires grown on copper treated with carbon, where the scale bar is 2500 nm. (7C) poly-crystalline nanowire in the initial stages, where the scale bar is 250 nm. (7D) developed poly-crystalline nanowire showing the unique morphology, where the scale bar is 250 nm.

FIGS. 8A-8C show (8A) TEM image of a poly-crystalline InP nanowire grown on a copper substrate treated with carbon. Multiple single-crystal grains ranging 20-40 nm are seen. The scale bar is 20 nm. (8B) magnified image of the nanowire in (8A) showing amorphous regions around the grains. The scale bar is 20 nm. (8C) diffraction pattern of the nanowire suggesting that the nanowire can be characterized dominantly by poly-crystalline, however multiple spots on the rings indicate that a set of specific planes {111} are more prevalent in the nanowire. The scale bar is 1.0 nm Dif.

FIGS. 9A-9C show X-ray diffraction on the (9A) carbon treated copper, (9B) Indium Phosphide nanowires grown on carbon treated copper, and (9C) Silicon nanowires grown on carbon treated copper.

### DETAILED DESCRIPTION

Thermoelectric devices require high electrical conductivity and low thermal conductivity for a higher performance level. However, these two qualities are linked; therefore making the efficiency of the thermoelectric devices difficult to improve. Nanowires allow electrical conductivity to be maintained by utilizing quantum effects when the nanowires are single-crystalline and of a small diameter. The boundaries of the nanowires allow the scattering of phonons reducing thermal conductivity. Poly-crystalline materials scatter phonons with a much higher efficiency than single-crystalline materials and still show promise as thermoelectric materials. The current invention provides a new material platform, single-polycrystalline core-shell nanowires, that utilizes the benefits of a single-crystalline nanowire to maintain electrical conductivity and that of a poly-crystalline material to reduce thermal conductivity lower than conventional nanowires of either (i.e., single-crystalline or poly-crystalline) type. An ensemble of single-poly-crystalline core-shell nanowires is an ideal material platform to improve efficiency of thermoelectric devices, according to the current invention. Furthermore, growing such nanowires directly on copper enables the production of large area flexible thermoelectric devices that have limitless applications.

In one example of the invention, copper (Cu) foils were rinsed with isopropanol and dried in air prior to carbon deposition. The carbon deposition was conducted by annealing the Cu foil in hydrogen at 990° C. for 20 minutes followed by a 10 minute deposition with a methane/hydrogen mixture, also at 990° C. and 270 mTorr. The foils were characterized using RAMAN spectroscopy to determine the nature of the grown carbon layer.

After the carbon deposition, the samples were coated with colloidal gold prepared from a 1 mMolar hydrogen tetrachloroaurate and 1% trisodium citrate solution. The gold coated Cu samples were allowed to dry in air at room temperature before being loaded in a PECVD for silicon nanowire growth. A pre-growth annealing process was performed at 400° C. for 5 min in hydrogen, which was followed by a nanowire growth step at growth temperature of 500° C. Disilane (Si2H6) hydrogen mixture was used as the silicon precursor and the flow rate was 10 sccm with a reactor pressure of 0.3 Torr and a growth time of 15 minutes. After the growth, the reaction chamber was evacuated and the sample was cooled to 50° C. in argon. The grown samples were characterized by scanning electron microscopy (SEM), energy dispersive x-ray spectroscopy (EDX), transmission electron microscopy (TEM), x-ray diffraction (XRD). In addition, a finite element analysis was used to assess thermal conductivities of three cases; single-crystalline nanowire, poly-crystalline nanowire, and single-poly-crystalline core-shell nanowire.

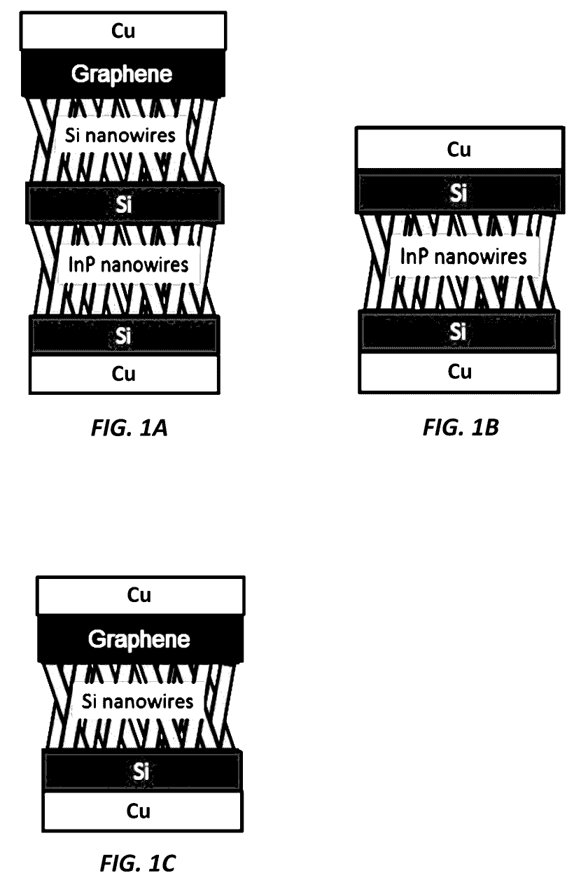

FIGS. 1A-1C show a thermoelectric device that includes a first flexible copper substrate having a carbon layer disposed on a polycrystalline flexible copper foil, a first nanowire structure disposed on the carbon layer, where the first nanowire structure includes a first lateral film layer disposed on the distal ends of the first nanowire structure, where the first lateral film layer connects the first nanowire structure distal ends, a second nanowire structure disposed on the first lateral film layer, where the second nanowire structure includes a second lateral film layer disposed on distal ends of the second nanowire structure, where the second lateral film layer connects the second nanowire structure distal ends, and a second flexible copper substrate disposed on the second lateral film layer.

According to one aspect of the invention, the polycrystalline copper foil includes a grapheme layer disposed on a flexible copper foil.

In another aspect of the invention, the first nanowire structure includes silicon nanowires. Here, the silicon nanowires include a core-shell structure, where the core structure includes a crystalline-core structure, where the shell structure includes a polycrystalline-shell structure.

In a further aspect of the invention, the first lateral film layer includes a silicon layer.

According to one aspect of the invention, the second nanowire structure includes indium phosphide nanowires.

In one aspect of the invention, the second lateral film layer includes a silicon layer.

According to another embodiment of the invention a thermoelectric device is provided that includes a flexible copper substrate having a graphene layer disposed on a polycrystalline copper foil a nanowire structure disposed on the graphene layer, where the nanowire structure includes a lateral film layer disposed on the ends of the nanowire structure, where the lateral film layer connects the nanowire structure ends, and a second flexible copper substrate disposed on the lateral film layer.

According to one aspect of the invention first nanowire structure includes silicon nanowires. Here, the silicon nanowires include a core structure and a shell structure, where the core structure includes a crystalline-core structure, where the shell structure includes a polycrystalline-shell structure.

In another aspect of the invention, the first lateral film layer includes a silicon layer.

In a further embodiment, the first nanowire structure includes Group Group IV, or Group V-VI nanowires.

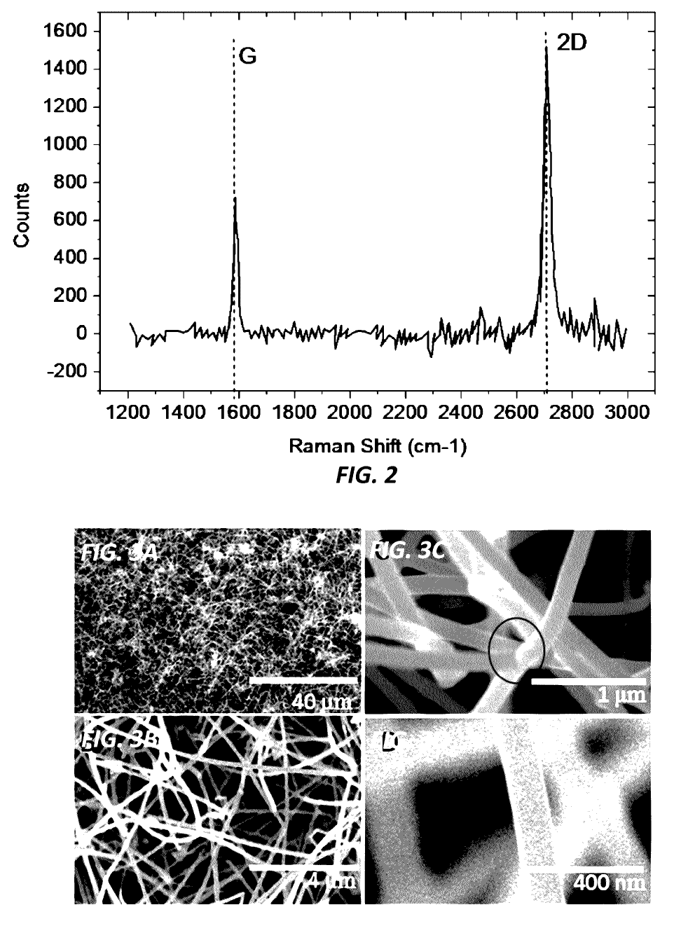

The results presented here show a method to grow semiconductor nanowires on copper and the structure of the grown silicon nanowires. The growth of silicon on copper without a carbon deposition resulted in polycrystalline silicon thin films, which indicates that the presence of a carbon layer is necessary for silicon nanowires to form on copper. This silicon nanowire growth is based on the vapor liquid solid mechanism with Au colloids serving as catalysts, the carbon layer serves as an orienting layer. To further demonstrate the role played by the carbon layer, a carbon layer formed on Cu foil substrates was studied by Raman spectroscopy. FIG. 2 shows the Raman spectrum taken from a copper foil substrate that underwent the carbon deposition process described above. Two peaks marked with “G” and “2D” are clearly seen and identified as two types of vibrational modes suggesting the presence of graphene on Cu foil substrates subjected to the carbon deposition process. The “2D” mode is to be sharper and more intense than the “G” mode showing that the graphene is a single layer.

FIGS. 3A-3D show SEM images of a network of Si nanowires grown on graphene on copper. FIG. 3A shows that the growth yielded a high density of Si nanowires over a large area, greater than 2 cm² of consistent coverage. In this example, the area was limited by the size of various deposition systems used for this demonstration and it is not a limitation.

A zoomed in image in FIG. 3B shows that nominal length of the nanowires appears to exceed 10 μm. This image also reveals that the nanowires are randomly orientated. Given poly-crystalline nature of the Cu foil substrates, it is expected that the Si nanowires lack a preferential crystallographic directionality over a large scale. In FIG. 3C, surrounded by the circle is one of the numerous intersections present in the nanowire network. These intersections would play critical roles in a thermoelectric device as they are expected to allow for the transport of electrical current over distances much longer than nominal length of individual nanowires while they scatter phonons. The image depicted in FIG. 3D indicates the nanowire diameter ˜130 nm of the Si nanowires.

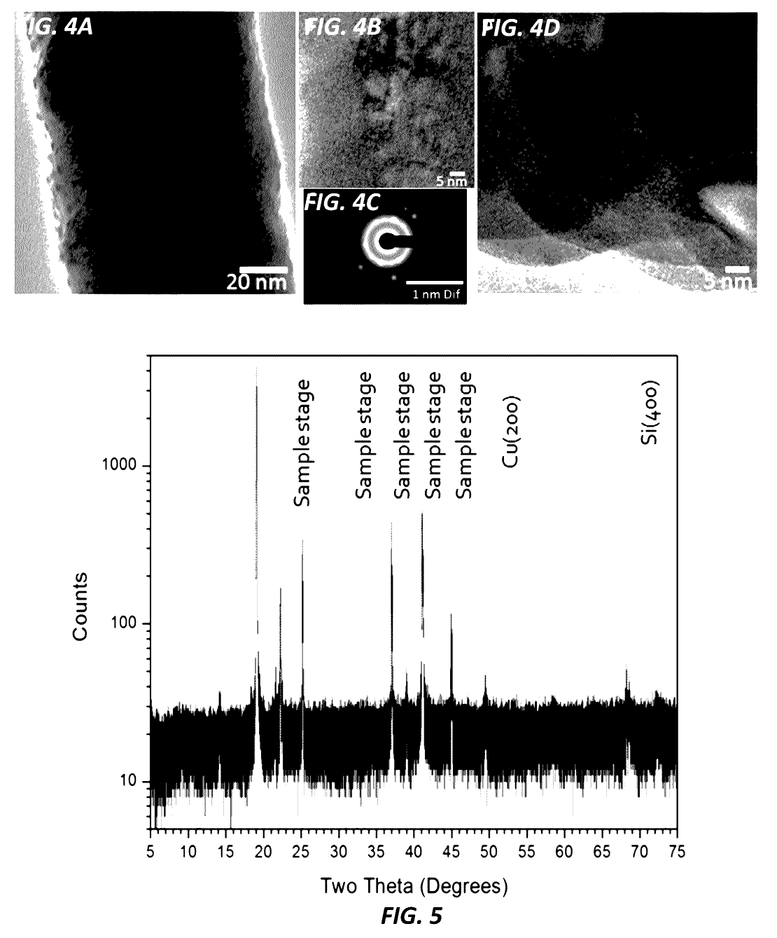

To investigate the structural properties of the grown Si nanowires, TEM was performed. FIG. 4A illustrates the internal structure of a representative nanowire. There appears to be substantial surface roughness (˜5 nm) that is not evident in the earlier SEM images. Also, the nanowire has two distinguishable sections; a single-crystalline core and a poly-crystalline shell. The core is magnified in FIG. 4B. Across the sample, diameter of the cores is in the range of 10-20 nm. The selective area diffraction taken on this core is displayed in FIG. 4C, which indicates that there is a single-crystalline portion and a poly-crystalline portion to within the nanowire and that they are made of Si. The zone axis is [110] and the core is in the [111] direction. The outer shell is further magnified in FIG. 4D, which reveals that it is poly-crystalline. There is an in-plane lattice mismatch (over 10.36%) between the Si [110] plane and the graphene (0001) plane. With this large mismatch, nanowires can still grow however. The large mismatch would yield significant strain within nanowires possibly causing spontaneous creation of a core-shell system. XRD was also performed on the sample. As indicated in FIG. 5, Cu(200) and Si(400) diffraction peaks suggest that Cu and Si nanowires are preferentially oriented along [100] direction of each of their respective f.c.c. lattice. It is likely that a portion of randomly oriented Si nanowires followed the crystallographic registry of the Cu substrate through a graphene layer. The presence of both Cu and Si was also confirmed by EDX.

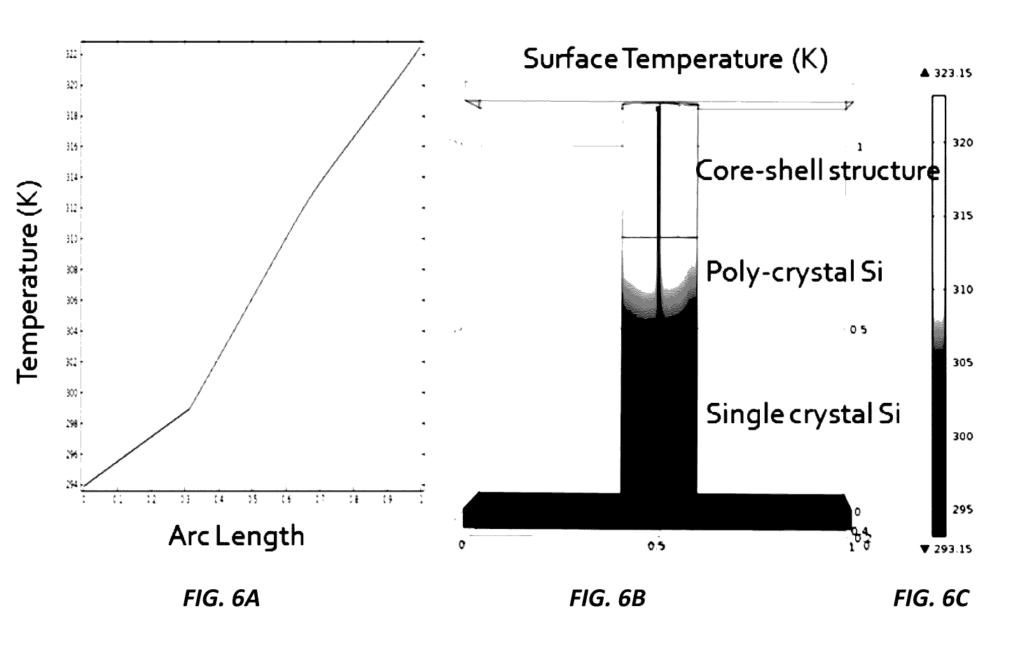

Finally finite element analysis was performed to gauge whether the single-poly-crystalline core-shell nanowires would exhibit physical properties advantageous to thermoelectrics. FIGS. 6A-6C show temperature plotted along a hypothetical nanowire composed of three segments for a given temperature difference (294 C-323.15 C). The top segment is made of the single-poly-crystalline core-shell structure described above. A Si nanowire with a single crystalline core and a poly-crystalline shell parallel to the temperature gradient that is dropped along that segment (313-323.15 degrees C. or 30.3° C./μm), with a core of 50 nm and a total diameter of 100 nm. The middle section is made of poly-crystalline Si with a thermal gradient of 42.42° C./μm with 299-313 degrees C. across it, and the bottom segment is made of single-crystalline Si with a thermal gradient of 15.15° C./μm, and temperatures of 294-299 degrees C. across it. The specific temperature gradient across a segment is related to thermal conductivity of the segment. The fact that the single-crystalline segment has the smallest gradient among the three, which indicates that the segment has the largest thermal conductivity as expected. As seen, the single-poly-crystalline core-shell segment shows a larger gradient than that of the single-crystalline segment, indicating a reduction in thermal conductivity. This analysis was also preformed in the opposite order (i.e., the single-poly-crystalline core-shell segment was connected to the low-temperature side) to confirm that the result was intrinsic and not associated with the geometrically asymmetric structure of the hypothetical nanowire.

There are many potential applications, from optoelectronic devices to thermoelectric devices that would benefit from utilizing low cost metallic substrates for growth of semiconductors, especially flexible metal foil substrates. Aluminum and copper, for instance, are low cost materials with excellent electrical and thermal conductivity, making them suitable electrode materials for devices. Heteroepitaxial growth of metal on semiconductor surfaces was extensively studied to develop high performance electrodes although poly-crystalline, rather than single-crystal, metal films simply deposited on semiconductor surfaces serve as acceptable electrodes. In contrast, growth of semiconductor directly on metallic surfaces has been limited to non-single crystal (i.e., poly-crystalline and amorphous) semiconductor films presumably because of the lack of to demand for single-crystal semiconductor epitaxially grown on metallic surfaces. For this reason, even emerging semiconductor nanostructures such as quantum dots and nanowires are almost exclusively grown on single-crystal semiconductor substrates with a few exceptions demonstrated on non-single crystal semiconductor surfaces. InP nanowires grown using copper seeds have been demonstrated, however, the demonstration involved a single crystalline InP substrate. New demonstrations were recently reported, in that, graphene enabled epitaxial growth of InAs nanowires on copper and InGaAs nanowires on MoS2 surfaces.

One of the main fields that could benefit from the growth of semiconductor nanostructures such as nanowires on poly-crystalline copper is thermoelectric devices. One of the key features for designing thermoelectric devices based on semiconductor nanowires is to utilize the electron transport properties of nanowires to maintain preferred electrical conductivity via quantum effects, i.e., ballistic transport. More importantly, rough surfaces of nanowires allow the scattering of phonons, therefore reducing thermal conductivity, another important aspect to increasing thermoelectric efficiency. In fact, phonon scattering has proven so essential to thermoelectric efficiency that poly-crystalline materials that scatter phonons with a much higher efficiency than that in single-crystalline materials show promise as a viable thermoelectric material platforms. In poly-crystalline materials containing grains with various size ranging from 3 nm to 1 μm, phonons with a wide range of wavelengths may be scattered efficiently, therefore increasing thermoelectric efficiency. Additionally grain boundaries can scatter phonons. From these preliminary demonstrations and design considerations, the current invention incorporates polycrystalline materials in the form of nanowires for thermoelectric devices to combine the benefits provided by both polycrystalline films and nanowires to achieve maximum phonon scattering.

In one example of the invention, InP and Si were used to demonstrate graphene's role in promoting the growth of nanowires of semiconductors including a group IV semiconductor, where the invention also includes groups III-V and V-VI. The example process demonstrates a method to grow semiconductors in the form of nanowires on poly-crystalline copper foils using graphene as an intermediate layer. InP nanowires are entirely polycrystalline while the Si nanowires have single-polycrystalline core-shell structures. These material platforms could offer unique benefits to engineer thermal and electrical conductivity for thermoelectric devices.

Four samples were prepared on mechanically flexible, non-single crystalline copper (Cu) foils, two of which were used for InP growth and the other two were for Si growth. The preparation of the two InP growth samples consisted of one Cu foil with carbon deposition and the other without carbon deposition. A Cu foil was cleaned with acetic acid, rinsed with DI water, and dried in air. Subsequently, carbon deposition was conducted by annealing the Cu foil in hydrogen at 990° C. and 270 mTorr for 20 minutes followed by low flow of methane/hydrogen mixture for 10 minutes, also at 990° C. and 270 mTorr. Following the carbon deposition, the Cu foil was allowed to cool in hydrogen, and then it was purged with argon before removal from the carbon deposition reactor. Another Cu foil was rinsed with acetone, isopropanol, methanol, rinsed in DI water, and dried in air. The two Cu foils; one with and the other without the carbon deposition, were further coated with Au colloidal nanoparticles with nominal diameters of 10 nm by drop casting and allowed to dry in air. Metal organic chemical vapor deposition (MOCVD) was used to deposit InP on the two Cu foils. The MOCVD growth conditions for InP were; growth time 20 minutes at 300 Torr, 550° C., and a 4.3 V/III molar flow rate ratio. The precursors were ditertiary butyl phosphine (DTBP) and trimethylindium (TMIn).

The preparation of the two Si growth samples also included one Cu foil with carbon deposition and the other without carbon deposition. Two Cu foils were cleaned with acetic acid, rinsed with DI water, and dried in air. Subsequently, one Cu foil underwent the carbon deposition described earlier. Following the carbon deposition, the Cu foil was allowed to cool in hydrogen then purged with argon before removal from the reactor. The other Cu foil did not undergo the carbon deposition. The two Cu foils; one with the carbon deposition and the other without it, were coated with colloidal gold. Plasma enhanced chemical vapor deposition (PECVD) was utilized to deposit silicon. The PECVD for Si included a pre-growth annealing process performed at 400° C. for 5 min in hydrogen, which was followed by a nanowire growth step at growth temperature of 500° C. Disilane (Si₂H₆) hydrogen mixture was used as the silicon precursor and the flow rate was 10 sccm with a reactor pressure of 0.3 Torr and a growth time of 15 minutes. After the growth the reaction chamber was evacuated and the sample was cooled to 50° C. in argon.

Four samples in total were fabricated in this example experiment; InP with carbon on Cu, InP without carbon on Cu, Si with carbon on Cu, and Si without carbon on Cu. All four samples, InP on Cu foils with/without carbon deposition and Si on Cu foils with/without carbon deposition, were characterized by various analytical tools including scanning electron microscopy (SEM) and energy dispersive x-ray spectroscopy (EDX). Transmission electron microscopy (TEM), Raman spectroscopy, and x-ray diffraction (XRD) were also utilized in this study.

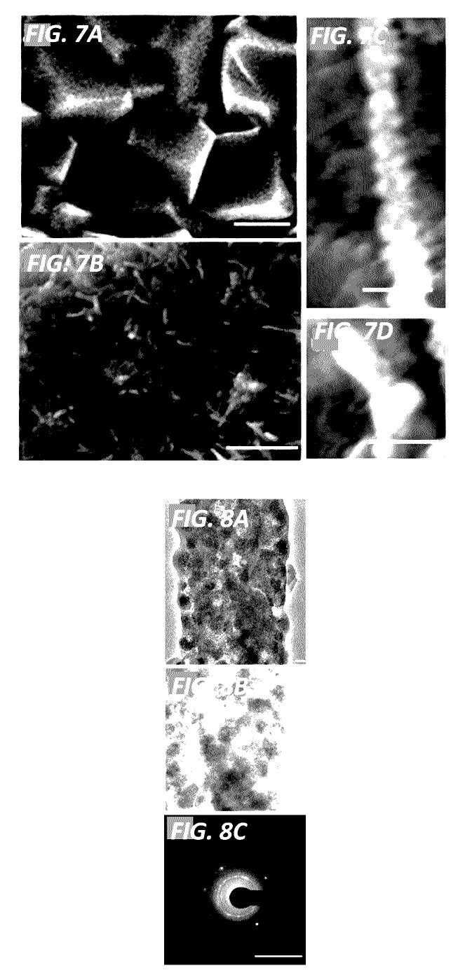

FIGS. 7A-7D show the InP growths using SEM. The SEM image shown in FIG. 7A, taken from the InP sample deposited on the Cu foil without carbon deposition, shows that a granular film was grown. The EDS confirmed that the grown film is composed of stoichiometric InP. While InP grew as films on Cu foils without a graphene intermediate layer, InP grew as nanowires on Cu foil with a graphene intermediate layer, as seen in FIGS. 7B-7D. Multiple nanowires appear to form from a central location in FIG. 7B. EDS indicates that their elemental composition includes indium and phosphorus with a chemical composition approximately stoichiometric InP. FIG. 7B demonstrates that a high density growth of InP nanowires can be grown on poly-crystalline Cu foils by using a graphene intermediate layer.

The image highlighted in FIG. 7C shows details of the rough surface morphology of the grown InP nanowires. A rough morphology of nanowires has been shown to reduce thermal conductivity, which is advantageous in thermoelectric applications. The image shown in FIG. 7D depicts a nanowire at its early stage of development with an Au metallic cap at the tip. TEM images of a representative InP nanowire are exhibited in FIGS. 8A-8C to explore microscopic structural characteristics of the nanowire. FIGS. 8A-8B, collected at two different magnifications, show granular features that indicate that the nanowire is not single phase. It appears to have larger grains with size of 40-120 nm likely to be formed by aggregation of small grains with size of 2-11 nm. FIG. 8C presents a corresponding selective area diffraction (SAD) pattern of the nanowire shown in FIGS. 8A-8B. The SAD pattern depicts several rings confirming that the nanowire is polycrystalline. The SAD pattern also displays bright spots on those rings associated with {111}f.c.c. InP crystalline planes.

As expected from the observation of InP films grown on Cu foils without a grapheme intermediate layer (FIG. 7A), the growth of silicon on copper without a graphene intermediate layer also resulted in the formation of silicon films with rough surfaces.

In contrast, as shown in SEM images in FIGS. 3A-3D, a network of Si nanowires were grown on a graphene intermediate layer on Cu foils. FIG. 3B illustrates a high density nanowire network over an area, greater than 2 cm₂ of consistent coverage. A nanowire network has the advantage that charge transport can utilize many paths to maximize conductivity. A low magnification image in FIG. 3B shows that nominal length of the nanowires exceeds 10 μm and the nanowires are randomly orientated. The image depicted in FIG. 3D indicates that the nanowire diameter is approximately 130 nm.

FIG. 4A illustrates the internal structure of a representative Si nanowire. There appears to be substantial surface roughness with magnitude ˜5 nm that is not obvious in the corresponding SEM images in FIGS. 3B-3D. The TEM indicates that the Si nanowires have two distinguishable sections that form a core-shell structure. The core is magnified in FIG. 4B, revealing that the core diameters range from 10 nm to 20 nm across the nanowire. A SAD pattern taken on the Si nanowire shown in FIGS. 4A-4B is displayed in FIG. 4C, which indicates that there is a single-crystalline portion and a poly-crystalline portion within the nanowire. The zone axis is [110] f.c.c. and the core was found to be single crystal and oriented f.c.c. [111] direction. The shell is further magnified in FIG. 4D, which, with the SAD pattern, confirms that it is poly-crystalline.

In summary, the growths of InP and Si on Cu foils yielded films on Cu foils. In contrast, the Cu foils covered with a graphene intermediate layer yielded InP and Si nanowire networks, which shows that the presence of a graphene layer was a necessary condition for nanowires to form on Cu foils.

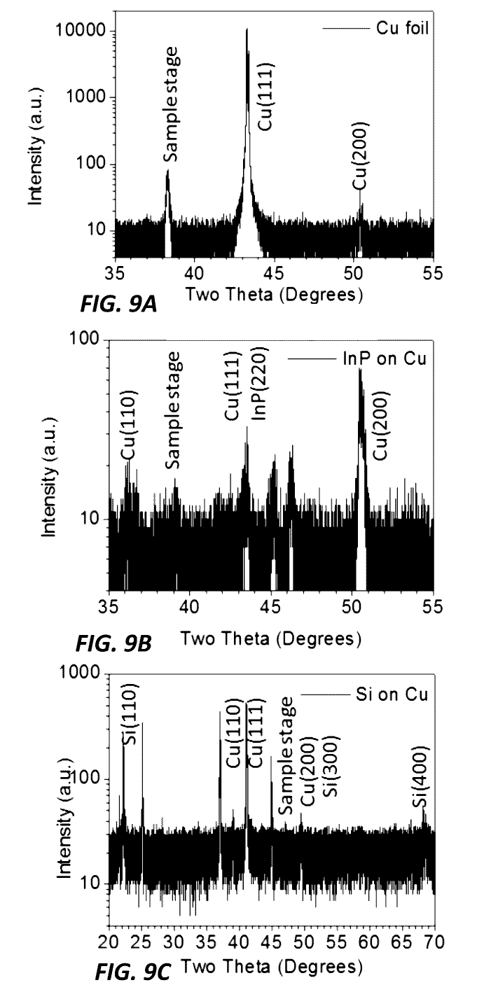

XRD was also performed on the nanowire samples as well as a Cu foil covered with a graphene intermediate layer to obtain further insights. As shown in FIG. 9A, XRD taken on a Cu foil covered with a graphene intermediate layer reveals several peaks. FIG. 6a collected from a Cu foil covered with a graphene intermediate layer shows Cu(111) as well as Cu(200) confirming that the copper used in our experiment was poly-crystalline. Interestingly, Cu (110) was also seen on Cu foils covered with a graphene intermediate layer in the two nanowire samples (i.e., InP and Si nanowire samples shown in FIG. 9B and FIG. 9C).

In the FIG. 9B data collected from the InP nanowire sample, Cu(111) and InP(220) peaks located closely each other appear to be a broad peak. The weak InP(220) signal can be attributed to the fact that total InP volume containing InP(220) planes that satisfy the Bragg condition is a small fraction of what it would have been for a single-crystal InP film with the same nominal thickness as that of an ensemble of InP nanowires. In addition, the InP nanowires are polycrystalline, which further reduces the peak intensity compared to that expected for a InP single-crystal film. For instance, based on an estimated maximum of 11% spatial coverage by the nanowires and average nanowire length of ˜10 μm, there would be ˜4×10¹⁴ nm³total volume or a thin film with thickness of approximately only ˜7 nm.

As indicated in FIG. 9C data collected from the Si nanowire sample, Cu(110), Si(110), Cu(200), Si(300), and Si(400) diffraction peaks suggest that Cu and Si nanowires are preferentially oriented along [100] and [110] direction of each of their respective f.c.c. lattice. It is unsurprising that the [110] contributor from InP and Si went unseen in the TEM diffraction as the zone axis were aligned with that family of planes. The XRD analysis presented here supports the TEM SAD data indicating a poly-crystalline nature of Si nanowires and of the Cu foils.

Additionally, Cu and Si interdifuse at their interface possibly suppressing the formation of nanowires when a graphene intermediate layer was absent. Cu and Si would have also formed a wide range of silicides, which could prevent nanowires from forming. A grapheme intermediate layer may have prevented the formation of the silicides as the XRD profile in FIG. 9C does not suggest that such silicides are present. In epitaxial growth of a thin film on a dissimilar thick substrate, there is, in general, a limit of how much mismatch strain can be accommodated by the thin film. The large mismatch between InP and Cu of 62% prevents epitaxial growth of thin film InP on Cu. Previously, InAs was epitaxially grown, by utilizing graphene as an intermediate orienting layer on copper. Zinc blende InAs orients along the <110> direction on (111) plane (the nearest-neighbor atomic distance of 0.428 nm). This allows the InAs to be well matched with the carbon honeycomb lattice along <1210> direction on the (0001) plane in the graphene of 0.426 nm spacing. This creates only a ˜0.5% misfit between InAs and graphene. This is possible through symmetry based growth on the graphene where the InAs f.c.c. lattice finds the closest matching arrangement of carbon bonds in the honeycomb graphene lattice unlike traditional heteroexpitaxial growth where the lattice mismatch arises from a small difference in atomic spacing rather than arrangement and spacing. Both InAs and InP have an f.c.c. lattice, but their bond lengths are significantly different; 0.428 nm for InAs and 0.415 nm for InP, respectively, along the <110> direction. Therefore a misfit of ˜2.6% is present between InP and graphene, which is much larger than that between InAs and graphene. 2.6% is a significant misfit for a symmetry based growth, which indicates substantial strain leads to polycrystalline InP nanowires, as we observed. The “natural” crystalline orientation of several semiconductors on graphene has been previously calculated. The large variation in lattice constants forces the different semiconductors to mate to the graphene honeycomb in different ways. For example, it was reported that the InP f.c.c. lattice (111) at 0.415 nm would conform to the 0.426 nm lattice of graphene. Essentially InP would naturally assume the same alignment on graphene along the (0001)/(111) registry.

Additionally in the formation of InGaAs on graphene, a core-shell structure was formed creating an InAs core and an InGaAs shell, suggesting strain accommodation can cause the formation of core-shell structures with a type of spinodal decomposition. However, Si and InP cannot break into multiple single crystalline materials, thus they would simply break into single-poly core shell and/or polycrystalline materials. In the examples herein, the Si nanowires may have exhibited a single-crystalline core with a poly-crystalline shell structure due to a large in-plane lattice mismatch of ˜9.6% between Si (111) and (0001) of graphene or, more likely, of ˜4% between graphene (0001) and 30% rotation with respect to the [110] direction of Si (111), creating sufficient strain to force defect creation in the form of a poly-crystalline shell. With this large mismatch, nanowires can still grow however, large mismatch would yield significant strain within nanowires possibly causing spontaneous creation of a core-shell structure. Another consideration is the use of DTBP in our MOCVD growth of InP, which would have increased the carbon interaction with the Cu substrate during the growth, possibly affecting the pre-existing graphene, while InAs and InGaAs were demonstrated using AsH3, which would have no effect on the graphene surface. Based on a series of studies with two different materials (i.e., Si and InP), it is concluded that the graphene intermediate layer that forms as a result of the carbon deposition serves as a template on poly-crystalline Cu.

Finite element analysis was used to compare thermal conductivity of the two specific nanowires experimentally obtained and characterized above, poly-crystalline nanowires and single-poly core-shell nanowires, with that of single crystalline nanowires. A model used to test if these structures would be beneficial was performed that included three μm long nanowires with diameters of 50 nm in parallel, with a separate model for each of the three nanowire structures. Si was used for all three types (i.e., single-crystal, poly-crystalline, single-poly core-shell) including the poly-crystalline component representing the InP nanowire growth as this analysis is intended to compare the structures; material composition variation would invalidate the structural comparison, therefore Si was used throughout the three cases.

The polycrystalline nanowire model is a simplified model of what is shown in FIGS. 8A-8C. As mentioned previously, structures made of grains with size ˜3-100 nm can increase phonon scattering along with grains from ˜0.1-1 μm. Secondly, the Si nanowire with a single crystalline core and a poly-crystalline shell, as shown in FIGS. 4A-4D, was modeled with a 10 nm core and a 40 nm shell. This analysis utilized an initial temperature of 3° K and set power input of 0.5 μW to heat the three nanowires until steady state temperatures are reached. Any temperature gradient differences can be interpreted as thermal conductivity differences as the provided heat, length, diameter, and model geometry are the same. Table 1 shows that the single-crystalline nanowire has the smallest gradient among the three, which indicates the largest thermal conductivity, as expected. The analysis shown in Table 1 suggests that the core shell structure will have a lower thermal conductivity than single crystal silicon, and a comparable thermal conductivity to that of poly-crystalline silicon. However, having a single crystalline core could maintain or even enhance electrical conductivity through ballistic transport in to comparison to that through nanowires entirely consisting of poly-crystalline materials, thus single-poly-crystalline core-shell structures might be a better choice for thermoelectrics. The finite element analyses performed on all three structures for comparisons indicate that the two structures; polycrystalline nanowires and single-poly-crystalline core-shell nanowires obtained in our experiment would reduce thermal conductivity.

TABLE 1
The resulting data from the three models where a fixed heat flow into the same
structure of different material configurations of Si resulted in different thermal
gradients due to altered thermal conductivities. Let Tₕ be the temperature at the
hot side, T_{c} be the temperature at the cold side, and ΔT be the temperature difference.

| | Single crystal | | Core-Shell | | Polycrystalline | |
|---|---|---|---|---|---|---|
| Th | 493.15 | K | 511.72 | K | 512.07 | K |
| Tc | 323.19 | K | 304.1 | K | 303.63 | K |
| ΔT | 169.96 | K | 207.62 | K | 208.44 | K |
| thermal gradient | 34 | K/μm | 41.5 | K/μm | 41.7 | K/μm |

The current invention used graphene to form nucleation sites for the growth of InP and Si nanowires on flexible Cu foils. The InP nanowires exhibit grains with a wide range of sizes that would allow the grains to be engineered for optimum scattering of phonons. The Si nanowire networks exhibit large poly-crystalline shells that would scatter phonons with rough surfaces and a large number of grain boundaries and single-crystalline cores that are advantageous for transport of electrons or holes. The two types of material platforms on mechanically flexible Cu foils are ideal thermoelectric devices. This technique allows for the use of flexible, metallic substrates for large area growth of semiconductor nanowires.

Further, the invention provides single-poly-crystalline core-shell nanowire growth for thermoelectrics applications. Semiconductor nanowires are directly grown on metal substrates using a graphene intermediate layer. A new design for nanowire based thermoelectric devices is provided that is based on a nanowire network composed of large wires for easy top contact with large poly-crystalline shells to scatter phonons with rough surfaces and many grain boundaries and single-crystalline cores for ballistic transport of electrons to maintain electrical conductivity. New devices based on nanometer-scale semiconductors directly integrated on metal substrates are provided.

In one embodiment, the growth of silicon core-shell nanowires with a crystalline-core and a polycrystalline-shell on copper substrates pretreated with carbon via Plasma Enhanced Chemical Vapor Deposition (PECVD) is disclosed. The nanowire diameters range from 120 to 250 nm with 10-20 nm crystalline cores. The overall large diameter enables easier methods of forming an electrical/thermal contact while the small core maintains the benefits of nanowires. By altering the copper surface with carbon, highly dense silicon nanowire networks can be directly grown on copper substrates, which enables efficient and economical incorporation of silicon nanowires into such applications as thermoelectric devices.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example, the total number of nanowire stacks in FIG. 1A is two; however the total number of nanowire stacks can be more than two. In another example, a first nanowire structure disposed on the carbon layer in FIGS. 1A and 1C, where the first nanowire structure includes a first lateral film layer disposed on the distal ends of the first nanowire structure, where the first lateral film layer connects the first nanowire structure distal ends, the first lateral film can be made of a material different from the first

1) A thermoelectric device, comprising:
a) a first flexible copper substrate, wherein said flexible copper substrate comprises a carbon layer disposed on a polycrystalline flexible copper foil;
b) a first nanowire structure disposed on said carbon layer, wherein said first nanowire structure comprises a first lateral film layer disposed on the distal ends of said first nanowire structure, wherein said first lateral film layer connects said first nanowire structure distal ends;
c) a second nanowire structure disposed on said first lateral film layer, wherein said second nanowire structure comprises a second lateral film layer disposed on distal ends of said second nanowire structure, wherein said second lateral film layer connects said second nanowire structure distal ends; and
d) a second flexible copper substrate disposed on said second lateral film layer.

2) The thermoelectric device of claim 1, wherein said polycrystalline copper foil comprises a graphene layer disposed on a flexible copper foil.

3) The thermoelectric device of claim 1, wherein said first nanowire structure comprises silicon nanowires.

4) The thermoelectric device of claim 3, wherein said silicon nanowires comprise a core-shell structure, where said core structure comprises a crystalline-core structure, wherein said shell structure comprises a polycrystalline-shell structure.

5) The thermoelectric device of claim 1, wherein said first lateral film layer comprises a silicon layer.

6) The thermoelectric device of claim 1, wherein said second nanowire structure comprises indium phosphide nanowires.

7) The thermoelectric device of claim 1, wherein said second lateral film layer comprises a silicon layer.

8) The thermoelectric device of claim 1, where the first nanowire structure includes Group III-V, Group IV, or Group V-VI nanowires.

9) A thermoelectric device, comprising:
a) a flexible copper substrate, wherein said flexible copper substrate comprises a graphene layer disposed on a polycrystalline copper foil;
b) a nanowire structure disposed on said graphene layer, wherein said nanowire structure comprises a lateral film layer disposed on the distal ends of said nanowire structure, wherein said lateral film layer connects said nanowire structure ends; and
c) a second flexible copper substrate disposed on said lateral film layer.

10) The thermoelectric device of claim 9, wherein said nanowire structure comprises silicon nanowires.

11) The thermoelectric device of claim 10, wherein said silicon nanowires comprises a core structure surrounded by a shell structure, where said core structure comprises a crystalline-core structure, wherein said shell structure comprises a polycrystalline-shell structure.

12) The thermoelectric device of claim 9, wherein said first lateral film layer comprises a silicon layer.

13) The thermoelectric device of claim 9, wherein said nanowire structure comprises Group III-V, Group IV, or Group V-VI nanowires.
